(19) United States
(12) Patent Application Publication
(10) Pub. No.: US 2021/0043495 A1
(43) Pub. Date: Feb. 11, 2021

(54) PLASMA PROCESSING DEVICE AND PLASMA PROCESSING METHOD

(71) Applicant: Kioxia Corporation, Minato-ku (JP)

(72) Inventor: Daichi KAWASAKI, Yokkaichi (JP)

(73) Assignee: Kioxia Corporation, Minato-ku (JP)

(21) Appl. No.: 16/810,935

(22) Filed: Mar. 6, 2020

(30) Foreign Application Priority Data
Aug. 5, 2019 (JP) 2019-143654

(51) Int. Cl. H01L 21/687; H01L 21/683; H01J 37/32

(52) U.S. Cl. CPC H01L 21/68735; H01L 21/6833; H01J 37/32568; H01J 2237/3343; H01J 37/32715; H01J 2237/002; H01J 2237/2007; H01J 37/32082

(57) ABSTRACT

A plasma processing device according to one embodiment includes an upper electrode located in a processing chamber; a board that is located in the processing chamber, opposing the upper electrode, and includes a lower electrode, and on which an intended substrate is placed; a radio-frequency power feeder that supplies radio frequency power in-between the upper electrode and the lower electrode; a dummy ring that surrounds an annular periphery of the intended substrate located on the board; and a cooler that cools the dummy ring from a location away from the intended substrate in a boundary region between the dummy ring and the intended substrate.

### CROSS-REFERENCE TO RELATED APPLICATIONS

This application is based upon and claims the benefit of priority from Japanese Patent Application No. 2019-143654, filed on Aug. 5, 2019; the entire contents of which are incorporated herein by reference.

### FIELD

An embodiment described herein relates generally to a plasma processing device and a plasma processing method.

### BACKGROUND

A plasma processing device is known, which includes an annular member that surrounds the outer circumference of a semiconductor wafer to control plasma in the vicinity thereof. Adjusting the top-surface position of such an annular member by vertically moving the member is also known. It is preferable for such a plasma processing device to avoid heat input to semiconductor wafers during plasma processing.

### BRIEF DESCRIPTION OF THE DRAWINGS

FIG. 1 is a view illustrating an exemplary configuration of a plasma processing device according to an embodiment;

FIG. 2 is a top view of a wafer and a dummy ring according to the embodiment;

FIG. 3 is a schematic enlarged view of a part including a cooler 20 in the plasma processing device of the embodiment;

FIGS. 4A to 4D are schematic views of part of the plasma processing device according to the embodiment; and

FIG. 5 is a flowchart illustrating an exemplary cooling-temperature adjusting process to the dummy ring in the embodiment.

### DETAILED DESCRIPTION

According to one embodiment, in general, a plasma processing device includes an upper electrode located in a processing chamber; a board that is located in the processing chamber, opposing the upper electrode, and includes a lower electrode, and on which an intended substrate is placed; a radio-frequency power feeder that supplies radio frequency power in-between the upper electrode and the lower electrode; a dummy ring that surrounds an annular periphery of the intended substrate located on the board; and a cooler that cools the dummy ring from a location away from the intended substrate in a boundary region between the dummy ring and the intended substrate.

An embodiment of a plasma processing device and a plasma processing method will be described in detail below with reference to the accompanying drawings. The following embodiment is merely exemplary and is not intended to limit the scope of the present invention. Elements disclosed in the embodiment below may include elements readily conceivable by those skilled in the art or substantially identical.

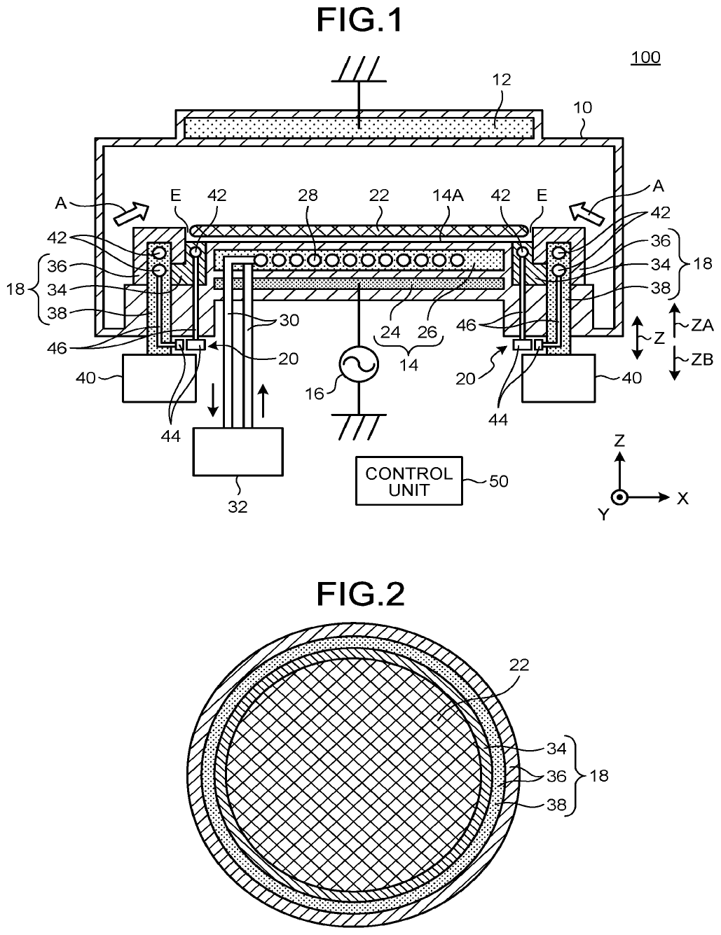

FIG. 1 is a view illustrating an exemplary configuration of a plasma processing device 100 of an embodiment.

The plasma processing device 100 includes a processing chamber 10, an upper electrode 12, a board 14, a radio-frequency power feeder 16, a dummy ring 18, coolers 20, and a control unit 50.

The processing chamber 10 is for plasma processing to a wafer 22. The processing chamber 10 includes a cylindrical vacuum container made of metal such as aluminum or stainless steel. Inside the processing chamber 10 the wafer 22 is subjected to plasma processing.

The upper electrode 12 is disposed in the processing chamber 10. The location of the upper electrode 12 is optional as long as it can generate plasma in-between the upper electrode 12 and the lower electrode 24, as described later. Specifically, the upper electrode 12 is located inside the processing chamber 10.

The wafer 22 is an exemplary substrate as a subject of plasma processing. The wafer 22 may be referred to as a semiconductor wafer or a semiconductor substrate.

The wafer 22 is placed on a mount surface 14A of the board 14. The board 14 is disposed inside the processing chamber 10, opposing the upper electrode 12. Specifically, the mount surface 14A of the board 14 faces the upper electrode 12 with spacing in the processing chamber 10.

The board 14 includes a lower electrode 24 and an insulator 26. The lower electrode 24 is placed, opposing the upper electrode 12 across the insulator 26 with spacing in the processing chamber 10.

The insulator 26 is an insulating member. The surface of the insulator 26 opposing the upper electrode 12 serves as the mount surface 14A on which the wafer 22 is placed. According to the present embodiment, the insulator 26 works as an electrostatic chuck that generates an electrostatic force to absorb the wafer 22 from the mount surface 14A. For example, the insulator 26 is made of ceramics, and provided with two metal electrodes inside to generate positive and negative charges on the mount surface 14A when applied with voltages of opposite polarities, and absorbs the wafer 22 from the mount surface 14A by Coulomb force.

The insulator 26 is provided with a plurality of independent flow channels 28 through which a heat transfer fluid (described later in detail) flows. The flow channels 28 are, for example, arranged in a spiral form on a two-dimensional plane along the mount surface 14A in the insulator 26. The material of the flow channels 28 is optional. The flow channels 28 are, for example, made of copper (Cu), covered with a heat conductive material such as ceramics, and embedded in the insulator 26. The flow channels 28 are connected to a supplier 32 through pipes 30. The supplier 32 supplies the heat transfer fluid to each of the flow channels 28 through the pipes 30. The supplied heat transfer fluid cools the wafer 22 located on the mount surface 14A.

The radio-frequency power feeder 16 serves to supply radio frequency power in-between the upper electrode 12 and the lower electrode 24. Specifically, the radio-frequency power feeder 16 is electrically connected to the lower electrode 24, and supplies power with a given frequency, e.g., a high frequency as 40 MHz to the lower electrode 24, contributing to plasma generation.

The dummy ring 18 is an annular member that surrounds the annular periphery of the wafer 22 located on the board 14. The dummy ring 18 may be referred to as a cover member or a focus ring.

The inner diameter of the dummy ring 18 can be optionally set as long as it is larger than the diameter of the wafer 22 on the mount surface 14A. The dummy ring 18 is disposed so as to surround the outer circumference of the wafer 22, i.e., the edge of the outer circumference of the disk-shaped wafer 22. The dummy ring 18 serves to control a plasma intensity in an outer circumferential region of the wafer 22. The outer circumference of the wafer 22 refers to the periphery, i.e., the edge of the outer circumference, of the surface of the disk-shaped wafer 22. The outer circumferential region of the wafer 22 refers to a given region excluding the center of the disk surface of the wafer 22, extending from the periphery to the center of the disk surface of the wafer 22.

According to the present embodiment, the dummy ring 18 includes an inner dummy ring 34, an outer dummy ring 36, and a support ring 38, for example. The structure of the dummy ring 18 is not limited to this example.

FIG. 2 is a top view of the wafer 22 and the dummy ring 18. As illustrated in FIG. 2, the inner dummy ring 34 is an annular member that surrounds the annular periphery of the wafer 22. The outer dummy ring 36 is an annular member located on the outer circumference of the inner dummy ring 34 concentrically with respect to the inner dummy ring 34. The support ring 38 is an annular member concentric with respect to the inner dummy ring 34 and the outer dummy ring 36.

Returning to FIG. 1, the inner dummy ring 34 is located on the inner circumference of the outer dummy ring 36. According to the present embodiment, the inner dummy ring 34 is disposed so as to surround the outer circumference of the board 14 and be concentric with respect to the columnar board 14. Further, the inner dummy ring 34 is disposed such that part of a vertically upstream end of the inner dummy ring 34 (indicated by arrow ZB) opposes a vertically bottom surface (downstream end indicated by arrow ZB) of the outer circumferential region of the wafer 22 placed on the board 14.

The support ring 38 is an annular member that supports the outer dummy ring 36. According to the present embodiment, the support ring 38 is disposed on the outer circumference of the inner dummy ring 34 concentrically with the inner dummy ring 34. Furthermore, the support ring 38 contacts with at least part of the bottom surface (vertically downstream end indicated by arrow ZB in FIG. 1) of the outer dummy ring 36 to support the outer dummy ring 36.

In the vertical direction indicated by arrow ZB, the upstream end of the support ring 38 contacts with the outer dummy ring 36 while the downstream end is connected to a driver 40.

The driver 40 serves to vertically move the outer dummy ring 36 supported by the support ring 38 by moving the support ring 38 upward and downward. Vertical movement refers to movement in a direction (indicated by arrow ZA in FIG. 1) opposite to the vertical direction and in the vertical direction (indicated by arrow ZB in FIG. 1). The directions indicated by the arrows ZA and ZB may be optional directions intersecting a horizontal direction indicated arrow X and arrow Y, and are not limited to directions parallel to the vertical direction. In the present embodiment, a two-dimensional plane defined by the direction of arrow X and the direction of arrow Y orthogonal to the arrow X is regarded as a plane matching the horizontal direction, however, it is not limited thereto.

The coolers 20 serve to cool the dummy ring 18 from a location distant from the wafer 22 in a boundary region E between the dummy ring 18 and the wafer 22,

The boundary region E is a region between the dummy ring 18 and the wafer 22 inside the processing chamber 10. Cooling the dummy ring from a location distant from the wafer 22 in the boundary region E refers to cooling the dummy ring 18 from the location farther from the wafer 22 than a contact surface of the dummy ring 18 with the boundary region E toward the contact surface, that is, toward the wafer 22 (arrow A direction).

According to the present embodiment, the coolers 20 each include flow channels 42 and suppliers 44. The flow channels 42 are arranged inside the dummy ring 18 to transfer the heat transfer fluid. The suppliers 44 supply the heat transfer fluid to the flow channels 42 through pipes 46.

The heat transfer fluid may be any fluid as long as it can transfer heat, and may be either a liquid or a gas. Heat transfer refers to drawing heat from outside the heat transfer fluid for cooling.

The heat transfer fluid being a liquid is, for example, cooling water or ethylene glycol. The heat transfer fluid being a gas is, for example, a He (helium) gas.

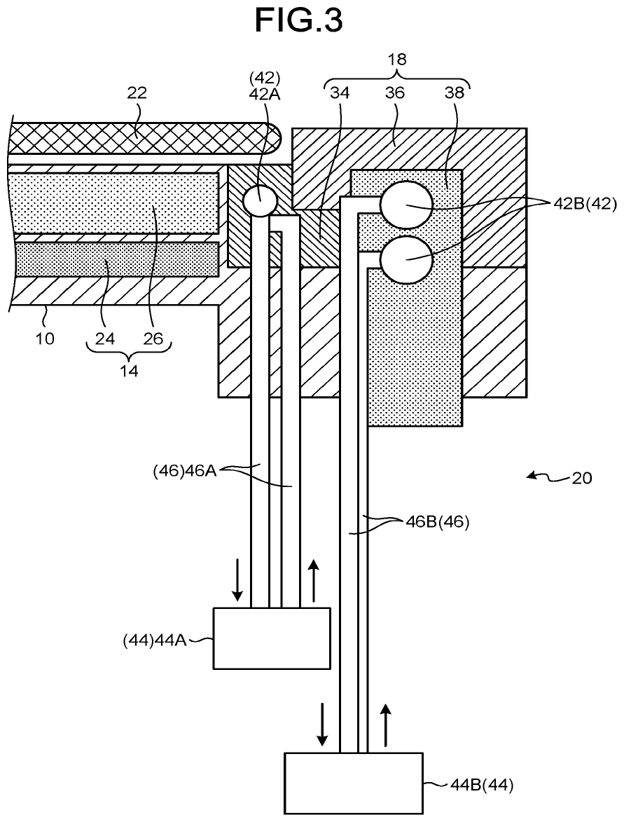

FIG. 3 is a schematic enlarged view of a part including the cooler 20 in the plasma processing device 100.

According to the present embodiment, the flow channels 42 include a first flow channel 42A and second flow channels 42B. The suppliers 44 include a first supplier 44A and a second supplier 44B.

The first flow channel 42A is located inside the inner dummy ring 34. The first flow channel 42A is connected to the first supplier 44A through pipes 46A. The first supplier 44A supplies the heat transfer fluid to the first flow channel 42A through the pipes 46A.

The second flow channels 42B are located on the inner side of the support ring 38. The second flow channels 42B are connected to the second supplier 44B through pipes 46B. The second supplier 44B supplies the heat transfer fluid to the second flow channels 42B through the pipes 46B.

The first supplier 44A supplies the heat transfer fluid through the first flow channel 42A to cool the inner dummy ring 34. Similarly, the second supplier 44B supplies the heat transfer fluid through the second flow channels 42B to cool the support ring 38 and the outer dummy ring 36 supported by the support ring 38.

In view of effectively cooling the dummy ring 18 including the inner dummy ring 34, the outer dummy ring 36, and the support ring 38, the flow channels 42 including the first flow channel 42A and the second flow channels 42B are preferably made of a heat conductive material. To effectively cool the dummy ring 18 including the inner dummy ring 34, the outer dummy ring 36, and the support ring 38 by the flow of the heat transfer fluid through the flow channels 42, the dummy ring 18 is preferably made of a heat conductive material.

Heat conductive refers to thermal conductivity sufficient to transfer the heat (cooling heat) of the heat transfer fluid in the flow channels 42 to at least the outer circumferential region of the wafer 22 located on the mount surface 14A through the dummy ring 18.

Specifically, preferable examples of the heat conductive material of the dummy ring 18 including the inner dummy ring 34, the outer dummy ring 36, and the support ring 38 include ceramics, e.g., aluminum oxide, silicon carbide, or yttrium oxyfluoride, or silicon dioxide or yttrium oxide being an aluminum base material coated with yttrium oxide. The dummy ring 18 is preferably made of a material, which will not substantially affect plasma processing to the wafer 22, when diffused in the vicinity of the wafer 22 by spattering during plasma processing, in addition to heat conductivity.

The flow channels 42 are preferably made of a heat conductive material, and may be made of the same material as or different materials from the dummy ring 18. The flow channels 42 made of the same material as the dummy ring 18 can be through holes in the dummy ring 18. The flow channels 28 made of a different material from the dummy ring 18 may be, for example, made of copper, and the dummy ring 18 may be made of ceramics. A combination of the materials of the dummy rings 18 and the flow channels 28 is not limited to this example.

The inner dummy ring 34, the outer dummy ring 36, and the support ring 38 of the dummy ring 18 may be made of the same material or different materials. The first flow channel 42A and the second flow channels 42B of the flow channels 42 may be made of the same material or different materials.

FIG. 3 illustrates one example that the inner dummy ring 34 is provided with the first flow channel 42A and the support ring 38 is provided with the second flow channels 42B. However, the flow channels 42 may extend inside at least one of the inner, dummy ring 34, the outer dummy ring 36, and the support ring 38. The outer dummy ring 36 may be handled as a consumable and a replacement part. Hence, in view of less degree of wear and less number of part replacements, and effectively reducing heat input to the outer circumferential region of the wafer 22, the flow channels 42 preferably extend in at least the support ring 38 among the inner dummy ring 34, the outer dummy ring 36, and the support ring 38.

The number and the shapes of the flow channels 42 (the first flow channel 42A and the second flow channels 42B) inside the dummy ring 18 can be optionally set. For example, the flow channels 42 are of a spiral form.

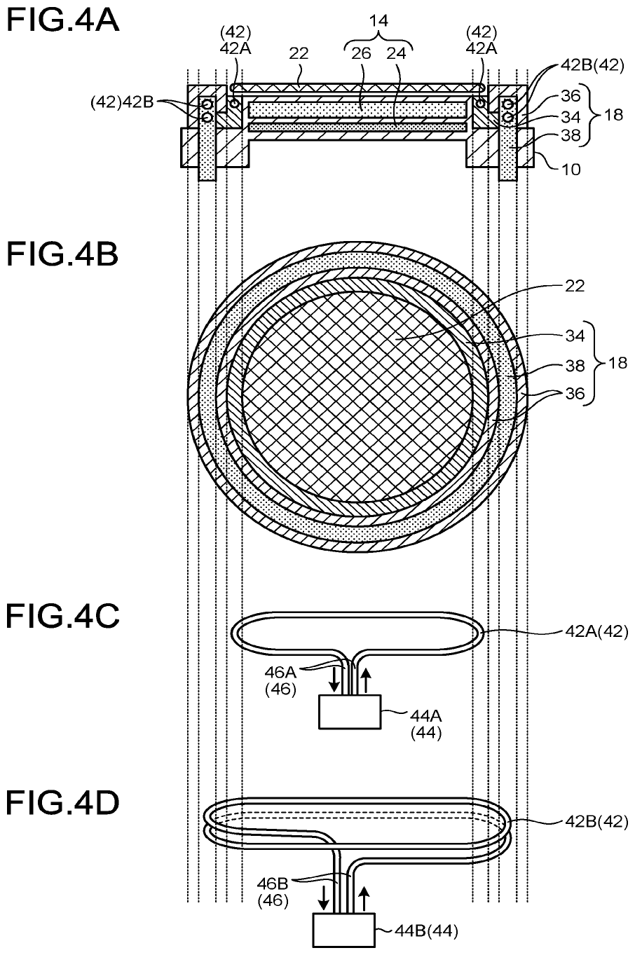

FIGS. 4A, 4B, 4C, and 4D are schematic views illustrating the spiral-form flow channels 42 and a positional relationship among the elements inside the dummy ring 18. Specifically, FIG. 4A is a schematic view of part of the plasma processing device 100. FIG. 4B is a top view of the wafer 22 and the dummy ring 18. FIG. 4C is a bird's eye view illustrating the position of the first flow channel 42A. FIG. 4D is a bird's eye view illustrating the position of the second flow channels 42B.

As illustrated in FIG. 4A, the first flow channel 42A extends inside the inner dummy ring 34, and the second flow channels 42B extend inside the support ring 38. As illustrated in FIG. 4B, the inner dummy ring 34 is located inside the support ring 38 and the outer dummy ring 36 being annular members. Hence, the first flow channel 42A is located inside or in the inner periphery of the second flow channels 42B.

As illustrated in FIG. 4C, for example, the first flow channel 42A is located inside the inner dummy ring 34 being an annular member, extending along the circumference of the inner dummy ring 34. As illustrated in FIG. 4D, for example, the second flow channels 42B are located inside the support ring 38 being an annular member, spirally extending along the circumference of the support ring 38 twice or more. The number of spirals of the first flow channel 42A and the second flow channels 42B is not limited to one or two.

Referring back to FIG. 3, the heat transfer fluid flowing in the first flow channel 42A and the heat transfer fluid flowing in the second flow channels 42B may be the same material or different materials. The heat transfer fluid flowing in the first flow channel 42A and the heat transfer fluid flowing in the second flow channels 42B may have the same temperature or different temperatures.

The heat transfer fluid flowing inside the support ring 38 being vertically moving annular member is preferably set to a lower temperature than the one flowing in the inner dummy ring 34. Specifically, the second supplier 44B preferably supplies the heat transfer fluid having a lower temperature to the second flow channels 42B than the heat transfer fluid supplied to the first flow channel 42A.

The plasma processing device 100 may include a plurality of outer dummy rings 36 that is vertically movable. In this case, the outer dummy rings 36 may include a plurality of annular members of mutually different diameters and being concentric to each other. In this case, at least one of the outer dummy rings 36 may be provided with the second flow channels 42B. Furthermore, it is preferable that the second supplier 44B regulate the heat transfer fluid flowing in the second flow channels 42B of at least one of the outer dummy rings 36 such that the heat transfer fluid flows at a lower temperature in the second flow channels 42B closer to the wafer 22.

Returning to FIG. 1, the control unit 50 controls the plasma processing device 100. Specifically, the control unit 50 is electrically connected to electronic devices such as the driver 40, the radio-frequency power feeder 16, and the suppliers 44 (the first supplier 44A and the second supplier 44B), and controls these electronic devices.

According to the present embodiment, during supply of radio frequency power in-between the upper electrode 12 and the lower electrode 24, i.e., during plasma processing to the wafer 22, the control unit 50 causes the suppliers 44 to adjust the cooling temperature of the dummy ring 18 in accordance with the temperature of the wafer 22 located on the mount surface 14A.

For example, the plasma processing device 100 includes, in the processing chamber 10, a sensor that senses the temperature of the outer circumferential region of the wafer 22. The sensor may be a temperature sensor that directly senses the temperature of the outer circumferential region of the wafer 22, or may be a device that detects the temperature of the outer circumferential region of the wafer 22 through image analysis of an image of the wafer 22. The control unit 50 controls the temperature of the heat transfer fluid flowing through the flow channels 42 so that the outer circumferential region of the wafer 22 has a given temperature, thereby adjusting the cooling temperature of the dummy ring 18.

Furthermore, the control unit 50 may pre-store relationship information between a plasma processing condition and the temperature of the outer circumferential region of the wafer 22, and use the relationship information to adjust the cooling temperature of the dummy ring 18. The plasma processing condition includes, for example, an elapsed time from start of plasma processing, but it is not limited to this example. In this case, the control unit 50 may determine the temperature of the outer circumferential region of the wafer 22 suitable for the plasma processing condition according to the relationship information, and control the temperature of the heat transfer fluid flowing inside the flow channels 42 such that the outer circumferential region of the wafer 22 has a given temperature, thereby adjust the cooling temperature of the dummy ring 18.

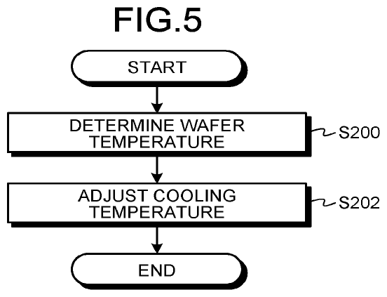

FIG. 5 is a flowchart illustrating an exemplary cooling-temperature adjusting process to the dummy ring 18. The control unit 50 determine the temperature of the outer circumferential region of the wafer 22 (Step S200), for example. The control unit 50 adjusts the cooling temperature of the dummy ring 18 according to the determined temperature (Step S202), completing this routine. The control unit 50 can repeat the processing illustrated in FIG. 5 during plasma processing.

In this regard, the control unit 50 or the supplier 44, i.e., the first supplier 44A and the second supplier 44B may execute the cooling-temperature adjusting processing to the dummy ring 18.

Returning to FIG. 1, in the plasma processing device 100 configured as above, the radio-frequency power feeder 16 supplies radio frequency power in-between the lower electrode 24 and the upper electrode 12. Supply of the radio frequency power starts the plasma processing to the wafer 22. During the plasma processing, the supplier 32 supplies the heat transfer fluid to the flow channels 28. Thereby, the contact surface of the wafer 22 with the mount surface 14A is cooled. Furthermore, the driver 40 drives the outer dummy ring 36 to be raised through the support ring 38. The amount of driving corresponds to a distance corresponding to an amount of wear of the outer dummy ring 36 due to the plasma processing. Thus, it is possible to reduce distortion of an ion sheath formed along the wafer 22 and the outer dummy ring 36 during the plasma processing. The driver 40 may drive the outer dummy ring 36 under control of the control unit 50.

According to the present embodiment, the cooler 20 cools the dummy ring 18 from a location distant from the wafer 22 in the boundary region E between the dummy ring 18 and the wafer 22.

As described above, in the present embodiment, the first supplier 44A supplies the heat transfer fluid to the first flow channel 42A inside the inner dummy ring 34, and the second supplier 44B supplies the heat transfer fluid to the second flow channels 42B inside the support ring 38.

By the heat transfer fluid flowing in the second flow channels 42B, the outer dummy ring 36 in contact with the support ring 38 is cooled through the support ring 38 having the second flow channels 42B inside. The outer dummy ring 36 is cooled, thereby avoiding heat input from the outer dummy ring 36 to the wafer 22.

By the heat transfer fluid flowing in the first flow channel 42A, the bottom surface of the outer circumferential region of the wafer 22 opposing the inner dummy ring 34 is cooled through the inner dummy ring 34 having the first flow channel 42A inside. This can prevent heat input from the inner dummy ring 34 to the outer circumferential region of the wafer 22.

As described above, the plasma processing device 100 according to the present embodiment includes the upper electrode 12 located in the processing chamber 10, the board 14, the radio-frequency power feeder 16, the dummy rings 18, and the coolers 20. The board 14 opposes the upper electrode 12 in the processing chamber 10, includes the lower electrode 24, and has the wafer 22 placed thereon. The radio-frequency power feeder 16 supplies the radio frequency power in-between the lower electrode 24 and the upper electrode 12. The dummy ring 18 includes an annular member that surrounds the annular periphery of the wafer 22 located on the board 14. The cooler 20 cools the dummy ring 18 from the location distant from the wafer 22 in the boundary region E between the dummy ring 18 and the wafer 22.

Thus, according to the present embodiment, the cooler 20 cools the dummy ring 18 from the location away from the wafer 22 in the boundary region E between the dummy ring 18 and the wafer 22. This can avoid heat input from the dummy ring 18 to the wafer 22.

Thus, the plasma processing device 100 of the present embodiment can avoid the heat input to the wafer 22 as an intended substrate during the plasma processing.

Furthermore, the plasma processing device 100 of the present embodiment can avoid the heat input to the outer circumferential region of the wafer 22, thereby reducing variation in etching rate, which would be caused due to unevenness in the surface temperature of the wafer 22 during the plasma processing. This can further prevent occurrence of a defect in the shape of the wafer 22. Consequently, the plasma processing device 100 of the present embodiment can improve a process margin of the wafer 22 and a device yield.

Further, according to the present embodiment, the cooler 20 cools the dummy ring 18 from the location away from the wafer 22 in the boundary region E between the dummy ring 18 and the wafer 22. During plasma processing, distortion of sheath may occur along with a variation in dielectric constant of the dummy-ring material caused by heat input to the dummy ring 18. However, according to the present embodiment, cooling the dummy ring produces temperature maintaining or adjusting effects, thereby avoiding the distortion of sheath.

Further, according to the present embodiment, the driver 40 works to vertically move the outer dummy ring 36 through the support ring 38. Hence, the driver 40 drive the outer dummy ring 36 to be raised through the support ring 38 by a distance corresponding to the amount of wear of the outer dummy ring 36 due to the plasma processing. Thereby, the plasma processing device 100 can prevent the distortion of ion sheath, in addition to the above effects.

That is, the plasma processing device 100 of the present embodiment can avoid the outer circumferential region of the wafer 22 from tilting, which would otherwise occur due to distortion of plasma sheath.

The present embodiment has described an example that the cooler 20 includes the flow channels 42 and the suppliers 44. However, the structure of the cooler 20 is not limited to the one including the flow channels 42 and the suppliers 44 as long as the cooler 20 can cool the dummy ring 18 from the location away from the wafer 22 in the boundary region E between the dummy ring 18 and the wafer 22.

For example, the dummy ring 18 may include, on the outer side, a cooling function in a position not opposing the wafer 22 and the boundary region E. For example, the dummy ring 18 may be provided with flow channels in a region of the outer periphery in contact with and not opposing the wafer 22 and the boundary region E.

While certain embodiments have been described, these embodiments have been presented by way of example only, and are not intended to limit the scope of the inventions. Indeed, the novel methods and systems described herein may be embodied in different other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A plasma processing device comprising:
an upper electrode located in a processing chamber;
a board that is located in the processing chamber, opposing the upper electrode, and includes a lower electrode, and on which an intended substrate is placed;
a radio-frequency power feeder that supplies radio frequency power in-between the upper electrode and the lower electrode;
a dummy ring that surrounds an annular periphery of the intended substrate located on the board; and
a cooler that cools the dummy ring from a location away from the intended substrate in a boundary region between the dummy ring and the intended substrate.

2. The plasma processing device according to claim 1, wherein the cooler includes
a flow channel located inside the dummy ring, and in which a heat transfer fluid flows, and
a supplier that supplies the heat transfer fluid to the flow channel.

3. The plasma processing device according to claim 2, further comprising
a driver that vertically moves the outer dummy ring through the support ring, wherein
the dummy ring comprises
an inner dummy ring that surrounds the annular periphery of the intended substrate,
an outer dummy ring located on an outer circumference of the inner dummy ring concentrically with the inner dummy ring, and
a support ring that is placed in contact with the outer dummy ring and supports the outer dummy ring, and
the flow channel extends inside at least one of the inner dummy ring, the outer dummy ring, and the support ring.

4. The plasma processing device according to claim 3, wherein
the flow channel extends inside at least the support ring.

5. The plasma processing device according to claim 3, wherein
the flow channel includes
a first flow channel that extends inside the inner dummy ring, and
a second flow channel that extends inside the support ring, and
the supplier includes
a first supplier that supplies the heat transfer fluid to the first flow channel, and
a second supplier that supplies the heat transfer fluid to the second flow channel.

6. The plasma processing device according to claim 4, wherein
the flow channel includes
a first flow channel that extends inside the inner dummy ring, and
a second flow channel that extends inside the support ring, and
the supplier includes
a first supplier that supplies the heat transfer fluid to the first flow channel, and
a second supplier that supplies the heat transfer fluid to the second flow channel.

7. The plasma processing device according to claim 5, wherein
the second supplier supplies, to the second flow channel, the heat transfer fluid having a temperature lower than the heat transfer fluid supplied to the first flow channel.

8. The plasma processing device according to claim 6, wherein
the second supplier transfers, to the second flow channel, the heat transfer fluid having a temperature lower than the heat transfer fluid flowing to the first flow channel.

9. The plasma processing device according to claim 2, wherein
the flow channel extends in a spiral form.

10. The plasma processing device according to claim 1, wherein
the dummy ring has heat conductivity.

11. A plasma processing method to be executed by a plasma processing device, the plasma processing device comprising an upper electrode located in a processing chamber; a board that is located in the processing chamber, opposing the upper electrode, and includes a lower electrode, and on which an intended substrate is placed; a radio-frequency power feeder that supplies radio frequency power in-between the upper electrode and the lower electrode; a dummy ring that surrounds an annular periphery of the intended substrate located on the board; and a cooler that cools the dummy ring from a location away from the intended substrate in a boundary region between the dummy ring and the intended substrate, the method comprising
adjusting a cooling temperature of the dummy ring according to a temperature of the intended substrate located on the board during supply of radio frequency power in-between the upper electrode and the lower electrode.
